(19) United States
(12) Patent Application Publication
(10) Pub. No.: US 2020/0044189 A1
(43) Pub. Date: Feb. 6, 2020

(54) GAS-BARRIER LAMINATED SHEET, PROCESS FOR PRODUCING GAS-BARRIER LAMINATED SHEET, AND ELECTRONIC MEMBER OR OPTICAL MEMBER

(71) Applicant: LINTEC Corporation, Tokyo (JP)

(72) Inventors: Satoshi NAGANAWA, Tokyo (JP); Takumi FURUYA, Tokyo (JP); Kenta NISHIJIMA, Tokyo (JP)

(73) Assignee: LINTEC Corporation, Tokyo (JP)

(21) Appl. No.: 16/340,282

(22) PCT Filed: Nov. 7, 2017
(86) PCT No.: PCT/JP2017/040065

§ 371 Date: Apr. 8, 2019

(30) Foreign Application Priority Data
Nov. 10, 2016 (JP) 2016-219498

(51) Int. Cl. H01L 51/52; C23C 14/06; C23C 14/34

(52) U.S. Cl. CPC H01L 51/5253; H01L 2251/5338; C23C 14/34; C23C 14/0676

(57) ABSTRACT

The present invention relates to: a gas-barrier laminated sheet having a layer structure of release sheet (A)/gas-barrier layer/adhesive resin layer/release sheet (B),
wherein arithmetic average roughness (Ra) of a surface on the release sheet (A) side of the gas-barrier layer is 5 nm or less, and maximum cross-section height (Rt) of the surface is 100 nm or less; a process for producing the gas-barrier laminated sheet; and an electronic member or an optical member, including a gas-barrier layer and an adhesive resin layer derived from the gas-barrier laminated sheet. The present invention provides: a gas-barrier laminated sheet excellent in sealing performance and bending properties and a process for producing the same, and an electronic member and an optical member including a gas-barrier layer and an adhesive resin layer derived from the gas-barrier laminated sheet.

### TECHNICAL FIELD

The present invention relates to a gas-barrier laminated sheet excellent in sealing performance and bending property, a process for producing the same, and an electronic member and optical member including a gas-barrier layer and an adhesive resin layer derived from the gas-barrier laminated sheet.

### BACKGROUND ART

Recently, organic EL elements draw attention as a light-emitting element capable of high-brightness emission by low-voltage direct-current driving.

However, there have been problems concerning organic EL elements that emission properties such as emission brightness, emission efficiency and emission uniformity deteriorate easily as time proceeds.

As a cause of this problem of the deterioration of emission properties, it is considered that oxygen, water vapor and the like penetrate into the inside of an organic EL element to deteriorate an electrode or organic layer. Then, some methods of using a sealing material have been proposed to solve the problem.

For example, Patent Literature 1 describes a tacky sheet for sealing having a gas-barrier layer and a tackifier layer at least on one surface on a base, the tackifier layer including a polyisobutylene-based resin (A) of weight-average molecular weight of 300,000-500,000 as a first component; a polybutene resin (B) of weight-average molecular weight of 1,000-250,000 as a second component; a hindered amine-based light stabilizer (C) as a third component; and/or a hindered phenol-based anti-oxidant (D), wherein the polybutene resin (B) is contained in 10-100 parts by mass relative to 100 parts by mass of the polyisobutylene-based resin (A).

Patent Literature 1 also describes that this tacky sheet for sealing has a very low water vapor transmission rate.

### CITATION LIST

### Patent Literature

Patent Literature 1: JP-A-2012-057065

### SUMMARY OF INVENTION

### Technical Problem

As described in Patent Literature 1, as a consequence of forming a gas-barrier layer and an adhesive resin layer on a base, a gas-barrier laminated sheet excellent in sealing performance can be obtained.

However, in a conventional gas-barrier laminated sheet having a base layer, sometimes problems were generated that bending properties were poor or sheet thinning was difficult.

The present invention has been achieved in consideration of the actual condition, and aims at providing a gas-barrier laminated sheet excellent in sealing performance and bending properties and a process for producing the same, and an electronic member and optical member including a gas-barrier layer and an adhesive resin layer derived from the gas-barrier laminated sheet.

### Solution to Problem

The present inventors studied hard about a gas-barrier laminated sheet having a gas-barrier layer and an adhesive resin layer to solve the above-described problem. As a result, the inventors found that a gas-barrier laminated sheet excellent in gas-barrier properties could be obtained as a consequence of a fact that 1) by producing a release sheet with a gas-barrier layer and a release sheet with an adhesive resin layer and by bonding these sheets together so that the gas-barrier layer of the release sheet with a gas-barrier layer faces the adhesive resin layer of the release sheet with an adhesive resin layer, a gas-barrier laminated sheet not having a base layer [that is, a gas-barrier laminated sheet having a layer structure of release sheet (A)/gas-barrier layer/adhesive resin layer/release sheet (B)] could be obtained, and that 2) arithmetic average roughness (Ra) and maximum cross-section height (Rt) of a surface on a release sheet (A) side of the gas-barrier layer were set to a specific value or less in the gas-barrier laminated sheet having this layer structure, to thereby complete the present invention.

Thus, according to the present invention, following (1)-(5) gas-barrier laminated sheets, (6) a process for producing the gas-barrier laminated sheet, and (7) an electronic member or an optical member are provided.

(1) A gas-barrier laminated sheet having a layer structure of release sheet (A)/gas-barrier layer/adhesive resin layer/release sheet (B), wherein arithmetic average roughness (Ra) of the surface on the release sheet (A) side of the gas-barrier layer is 5 nm or less, and maximum cross-section height (Rt) of the surface is 100 nm or less.

(2) The laminate according to (1), wherein the gas-barrier layer is one that is constituted of an inorganic vapor-deposited film, or one in which a surface of a layer containing a polymer compound has been modified.

(3) The gas-barrier laminated sheet according to (1) or (2), wherein the adhesive resin layer is one that is formed using a rubber-based adhesive resin, a polyolefin-based adhesive resin or an epoxy-based adhesive resin.

(4) The gas-barrier laminated sheet according to any of (1)-(3), wherein a water vapor transmission rate of the release sheet (B) under an atmosphere of 40° C. in temperature and 90% in relative humidity is 1 g/m²/day or less.

(5) The gas-barrier laminated sheet according to any of (1)-(4), which is a laminated sheet for an electronic member or for an optical member.

(6) A process for producing the gas-barrier laminated sheet according to any of (1)-(5), including following steps 1-3:

step 1: forming a gas-barrier layer on a surface having a release property of a first release sheet, the surface being 5 nm or less in arithmetic average roughness (Ra) and 100 nm or less in maximum cross-section height (Rt), to thereby give a release sheet with the gas-barrier layer;

step 2: forming an adhesive resin layer on a surface having a release property of a second release sheet to thereby give a release sheet with the adhesive resin layer; and

step 3: bonding the release sheet with the gas-barrier layer together with the release sheet with the adhesive resin layer so that the gas-barrier layer of the release sheet with the gas-barrier layer faces the adhesive resin layer of the release sheet with the adhesive resin layer.

(7) An electronic member or an optical member, including a gas-barrier layer and an adhesive resin layer derived from the gas-barrier laminated sheet according to any of (1)-(5).

### Advantageous Effects of Invention

According to the present invention, there are provided a gas-barrier laminated sheet excellent in sealing performance and bending properties and a process for producing the same, and an electronic member and an optical member including a gas-barrier layer and an adhesive resin layer derived from the gas-barrier laminated sheet.

### DESCRIPTION OF EMBODIMENTS

Hereinafter, the present invention will be explained in detail, while classifying the invention into items of 1) a gas-barrier laminated sheet, 2) a process for producing the gas-barrier laminated sheet, and 3) an electronic member or an optical member.

1) Gas-Barrier Laminated Sheet

The gas-barrier laminated sheet of the present invention is a gas-barrier laminated sheet having a layer structure of release sheet (A)/gas-barrier layer/adhesive resin layer/release sheet (B), in which arithmetic average roughness (Ra) of the surface on the release sheet (A) side of the gas-barrier layer is 5 nm or less, and maximum cross-section height (Rt) of the surface is 100 nm or less.

Meanwhile, in this description, a “sheet” includes not only a strip-shaped one but also a long-sized (belt-shaped) one.

“Long-sized” means that, relative to a width direction of a sheet, the sheet has length of at least around 5 times or greater, preferably 10 times or greater, and that specifically it has approximate length to be stored or conveyed wound in a roll shape.

[Gas-Barrier Layer]

A gas-barrier layer constituting the gas-barrier laminated sheet of the present invention is a layer having properties of suppressing transmission of oxygen and water vapor (in this description, may be referred to as “gas-barrier properties”).

A water vapor transmission rate of the gas-barrier layer of the gas-barrier laminated sheet of the present invention is, under an atmosphere of 40° C. in temperature and 90% in relative humidity, usually 1.0 g/m²/day or less, preferably 0.8 g/m²/day or less, more preferably 0.5 g/m²/day or less, and furthermore preferably 0.1 g/m²/day or less. In the present invention, the water vapor transmission rate of the gas-barrier layer shall substantially be considered as a value of a water vapor transmission rate of the tackily adhesive sheet. The water vapor transmission rate of the tackily adhesive sheet can be measured using a known gas transmission rate measurement apparatus. Specifically, it can be measured by a method described in Example.

Thickness of the gas-barrier layer lies, from the viewpoint of the gas-barrier property and handling property, within a range of usually 1-2000 nm, preferably 3-1000 nm, more preferably 5-500 nm and furthermore preferably 40-200 nm.

The arithmetic average roughness (Ra) of the surface on the release sheet (A) side of the gas-barrier layer is 5 nm or less, and preferably 3 nm or less. The lower limit value is not particularly determined, and is usually 0.1 nm or more. Accordingly, the arithmetic average roughness (Ra) of the surface is usually 0.1-5 nm, and preferably 0.1-3 nm.

The maximum cross-section height (Rt) of the surface on the release sheet (A) side of the gas-barrier layer is 100 nm or less, and preferably 50 nm or less. The lower limit value is not particularly determined, and is usually 10 nm or more. Accordingly, the maximum cross-section height (Rt) of the surface is usually 10-100 nm, and preferably 10-50 nm. Gas-barrier layers having such surface are more excellent in gas-barrier properties.

Gas-barrier layers having such surface can be formed effectively by using a release sheet (A) excellent in smoothness.

The arithmetic average roughness (Ra) and maximum cross-section height (Rt) of the surface of the gas-barrier layer can be obtained by exfoliating the release sheet (A) from the gas-barrier laminated sheet and, after that, observing an exposed surface of the gas-barrier layer with a light interference microscope.

The observation with a light interference microscope can be performed according to a method described in Example.

A material and the like of a gas-barrier layer is not particularly limited, as long as the layer has gas-barrier properties. For example, there are exemplified a gas-barrier layer constituted of an inorganic vapor-deposited film, a gas-barrier layer containing a gas-barrier resin, a gas-barrier layer obtained by modifying a surface of a layer containing a polymer compound (hereinafter, may be referred to as a “polymer layer”) [in this case, a gas-barrier layer means not only a modified region but also a “polymer layer containing the modified region” ], and the like.

Among these, because a layer that is thin and excellent in gas-barrier properties can be formed effectively, a gas-barrier layer constituted of an inorganic vapor-deposited film, or a gas-barrier layer obtained by modifying a surface of a polymer layer is preferable.

An inorganic vapor-deposited film includes a vapor-deposited film of an inorganic compound and a vapor-deposited film of a metal.

Raw materials of a vapor-deposited film of an inorganic compound include inorganic oxides such as silicon oxide, aluminum oxide, magnesium oxide, zinc oxide, indium oxide and tin oxide; inorganic nitrides such as silicon nitride, aluminum nitride and titanium nitride; inorganic carbides; inorganic sulfides; inorganic oxynitrides such as silicon oxynitride; inorganic oxycarbides; inorganic nitridecarbides; inorganic oxynitride carbides; and the like.

Raw materials of a vapor-deposited film of a metal include aluminum, magnesium, zinc, tin and the like.

These can be used in one kind alone, or in two or more kinds in combination.

Among these, from a standpoint of gas-barrier properties, inorganic vapor-deposited films derived from an inorganic oxide, inorganic nitride or metal as a raw material are preferable, and, from a standpoint of transparency in addition, inorganic vapor-deposited films derived from an inorganic oxide or inorganic nitride as a raw material are preferable. Moreover, the inorganic vapor-deposited film may have a single layer or multilayer.

Thickness of the inorganic vapor-deposited film is, from the viewpoint of gas-barrier properties and handling properties, within a range of preferably 1-2000 nm, more preferably 3-1000 nm, further preferably 5-500 nm, and furthermore preferably 40-200 nm.

Processes for forming the inorganic vapor-deposited film are not particularly limited, and known processes can be employed. Examples thereof include PVD processes such as a vacuum deposition process, a sputtering process and an ion plating process, CVD processes such as a thermal CVD process, a plasma CVD process and a photo-CVD process, and an atomic layer deposition process (ALD process).

Examples of the gas-barrier resins include resins that hardly allow oxygen, water vapor and the like to transmit themselves, such as polyvinyl alcohol or partially saponified product thereof, ethylene-vinyl alcohol copolymer, polyacrylonitrile, polyvinyl chloride, polyvinylidene chloride, polychlorotrifluoroethylene and the like.

Thickness of a gas-barrier layer containing a gas-barrier resin is, from the viewpoint of gas-barrier properties, within a range of preferably 1-2000 nm, more preferably 3-1000 nm, further preferably 5-500 nm, and furthermore preferably 40-200 nm.

Processes for forming a gas-barrier layer containing a gas-barrier resin include a process of applying a solution containing the gas-barrier resin onto a release sheet (A) and suitably drying the obtained coating film.

Application processes of the resin solution are not particularly limited, including a spin coating process, a spray coating process, a bar coating process, a knife coating process, a roll coating process, a blade coating process, a die coating process, a gravure coating process, and the like.

As a process for drying a coating film, conventionally known drying processes can be utilized, including hot air drying, hot roll drying, infrared ray irradiation, and the like.

In a gas-barrier layer constituted by modifying a surface of a polymer layer, polymer compounds to be used include a silicon-containing polymer compound, polyimide, polyamide, polyamide-imide, polyphenylene ether, polyether ketone, polyether ether ketone, polyolefin, polyester, polycarbonate, polysulfone, polyethersulfone, polyphenylene sulfide, polyarylate, acrylic-based resins, alicyclic hydrocarbon-based resins, aromatic-based polymers, and the like.

These polymer compounds can be used in one kind alone, or in two or more kinds in combination.

The polymer layer may contain other components in a range that does not inhibit the purpose of the present invention, in addition to the polymer compound. Other components include a curing agent, an anti-aging agent, a light stabilizer, a flame retardant, and the like.

Content of the polymer compound in the polymer layer is preferably 50% by mass or more, and more preferably 70% by mass or more, because a gas barrier layer having a more excellent gas barrier property can be obtained.

Thickness of the polymer layer is not particularly limited, and is usually 20 nm to 50 μm, preferably 30 nm to 1 μm, and more preferably 40 nm to 500 nm.

The polymer layer can be formed, for example, by applying a liquid of a polymer compound dissolved or dispersed in an organic solvent onto a release sheet by a known coating process and drying the obtained coating film.

Organic solvents include aromatic hydrocarbon-based solvents such as benzene and toluene; ester-based solvents such as ethyl acetate and butyl acetate; ketone-based solvents such as acetone, methyl ethyl ketone and methyl isobutyl ketone; aliphatic hydrocarbon-based solvents such as n-pentane, n-hexane and n-heptane; alicyclic hydrocarbon-based solvents such as cyclopentane and cyclohexane; and the like.

These solvents can be used in one kind alone, or in two or more kinds in combination.

Application processes include a bar-coating process, a spin-coating process, a dipping process, a roll-coating process, a gravure-coating process, a knife-coating process, an air knife-coating process, a roll knife-coating process, a die-coating process, a screen printing process, a spray-coating process, a gravure offset process, and the like.

Processes for drying a coating film include conventionally known drying processes such as hot air drying, hot roll drying and infrared ray irradiation. Heating temperature is usually 80-150° C., and heating time is usually several tens of seconds to several tens of minutes.

Processes for modifying a surface of the polymer layer include an ion implantation treatment, a plasma treatment, an ultraviolet ray irradiation treatment, a heat treatment, and the like.

The ion implantation treatment is a process of implanting accelerated ions into the polymer layer to thereby modify the polymer layer, as described later.

The plasma treatment is a process of exposing the polymer layer in plasma to thereby modify the polymer layer. For example, the plasma treatment can be performed according to the process described in JP-A-2012-106421.

The ultraviolet ray irradiation treatment is a process of irradiating a polymer layer with ultraviolet rays to thereby modify the polymer layer. For example, an ultraviolet ray modification treatment can be performed according to the process described in JP-A-2013-226757.

Among these gas barrier layers, because of a more excellent gas barrier property, one obtained by subjecting a layer containing a silicon-containing polymer compound to an ion implantation treatment is preferable.

Silicon-containing polymer compounds include polysilazane-based compounds, polycarbosilane-based compounds, polysilane-based compounds, polyorganosiloxane-based compounds, poly(disilanylenephenylene)-based compounds, poly(disilanyleneethynylene)-based compounds and the like, and polysilazane-based compounds are more preferable.

Polysilazane-based compounds are compounds having a repeating unit containing a —Si—N— bond (silazane bond) in a molecule. Specifically,

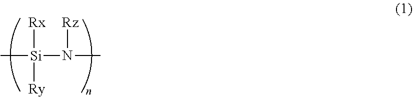

compounds having a repeating unit represented by a formula (1) are preferable. Moreover, although number average molecular weight of a polysilazane-based compound to be used is not particularly limited, it is preferably 100-50,000.

In the formula (1), n represents an arbitrary natural number. Rx, Ry and Rz each independently represents a hydrogen atom, and a non-hydrolyzable group such as an unsubstituted or substituted alkyl group, an unsubstituted or substituted cycloalkyl group, an unsubstituted or substituted alkenyl group, an unsubstituted or substituted aryl group or alkylsilyl group.

Examples of alkyl groups of the unsubstituted or substituted alkyl group include alkyl groups each having 1-10 carbon atoms such as a methyl group, an ethyl group, a n-propyl group, an isopropyl group, a n-butyl group, an isobutyl group, a sec-butyl group, a t-butyl group, a n-pentyl group, an isopentyl group, a neopentyl group, a n-hexyl group, a n-heptyl group and a n-octyl group.

Examples of cycloalkyl groups of the unsubstituted or substituted cycloalkyl group include cycloalkyl groups each having 3-10 carbon atoms such as a cyclobutyl group, a cyclopentyl group, a cyclohexyl group and a cycloheptyl group.

Examples of alkenyl groups of the unsubstituted or substituted alkenyl group include alkenyl groups each having 2-10 carbon atoms such as a vinyl group, a 1-propenyl group, a 2-propenyl group, a 1-butenyl group, a 2-butenyl group and a 3-butenyl group.

Substituents of the alkyl group, cycloalkyl group and alkenyl group include halogen atoms such as a fluorine atom, a chlorine atom, a bromine atom and an iodine atom; a hydroxyl group; a thiol group; an epoxy group; a glycidoxy group; a (meth)acryloyloxy group; unsubstituted or substituted aryl groups such as a phenyl group, a 4-methylphenyl group and a 4-chlorophenyl group; and the like.

Examples of aryl groups of the unsubstituted or substituted aryl groups include aryl groups each having 6-15 carbon atoms such as a phenyl group, a 1-naphthyl group and a 2-naphthyl group.

Substituents of the aryl group include halogen atoms such as a fluorine atom, a chlorine atom, a bromine atom and an iodine atom; alkyl groups each having 1-6 carbon atoms such as a methyl group and an ethyl group; alkoxy groups each having 1-6 carbon atoms such as a methoxy group and an ethoxy group; a nitro group; a cyano group; a hydroxyl group; a thiol group; an epoxy group; a glycidoxy group; a (meth)acryloyloxy group; unsubstituted or substituted aryl groups such as a phenyl group, a 4-methylphenyl group and a 4-chlorophenyl group; and the like.

Alkylsilyl groups include a trimethylsilyl group, a triethylsilyl group, a triisopropylsilyl group, a tri-t-butylsilyl group, a methyldiethylsilyl group, a dimethylsilyl group, a diethylsilyl group, a methylsilyl group, an ethylsilyl group, and the like.

Among these, as Rx, Ry and Rz, a hydrogen atom, alkyl groups each having 1-6 carbon atoms, or a phenyl group is preferable, and a hydrogen atom is particularly preferable.

Polysilazane-based compounds having a repeating unit represented by the formula (1) may be either of inorganic polysilazane in which all Rx, Ry and Rz are hydrogen atoms or organic polysilazane in which at least one of Rx, Ry and Rz is not a hydrogen atom.

Moreover, in the present invention, a polysilazane-modified product may be used as the polysilazane-based compound. Examples of polysilazane-modified products include those described in JP-A-62-195024, JP-A-2-84437, JP-A-63-81122, JP-A-1-138108, JP-A-2-175726, JP-A-5-238827, JP-A-5-238827, JP-A-6-122852, JP-A-6-306329, JP-A-6-299118, JP-A-9-31333, JP-A-5-345826, JP-A-4-63833, and the like.

Among these, from the viewpoint of availability and capability of forming an ion implantation layer having excellent gas barrier properties, perhydropolysilazane, in which all Rx, Ry and Rz are hydrogen atoms, is preferable as the polysilazane-based compound.

Moreover, as a polysilazane-based compound, commercial products available as a glass coating material and the like can be used as is.

Polysilazane-based compounds can be used in one kind alone, or in two or more kinds in combination.

Ions to be implanted in a polymer layer include ions of rare gases such as argon, helium, neon, krypton and xenon; ions of fluorocarbon, hydrogen, nitrogen, oxygen, carbon dioxide, chlorine, fluorine and sulfur; ions of alkane-based gases such as methane and ethane; ions of alkene-based gases such as ethylene and propylene; ions of alkadiene-based gases such as pentadiene and butadiene; ions of alkyne-based gases such as acetylene; ions of aromatic hydrocarbon-based gases such as benzene and toluene; ions of cycloalkane-based gases such as cyclopropane; ions of cycloalkene-based gases such as cyclopentene; ions of metals; ions of organic silicon compounds; and the like.

These ions can be used in one kind alone, or in two or more kinds in combination.

Among these, ions of rare gases such as argon, helium, neon, krypton and xenon are preferable, because these ions may be implanted in a more easy and simple way to give a gas barrier layer having more excellent gas barrier properties.

An implantation amount of ions can be suitably determined in accordance with an intended purpose (necessary gas barrier properties, transparency, etc.) of a laminated sheet, and the like.

Process for implanting ions include a process of irradiating a polymer layer with ions accelerated by an electric field (ion beam), a process of implanting ions in plasma, and the like. Among these, the latter process of implanting ions in plasma (plasma ion implantation process) is preferable because an intended gas-barrier layer can be formed in an easy and simple way.

A plasma ion implantation process can be performed, for example, by generating plasma under an atmosphere containing a plasma generation gas such as a rare gas and applying negative high voltage pulse to a polymer layer to thereby implant ions (positive ions) in the plasma into a surface part of the polymer layer. The plasma ion implantation process can be performed, more specifically, by a process described in WO 2010/107018 brochure or the like.

Thickness of a region into which ions are to be implanted by ion implantation can be controlled by implantation conditions such as the kind of the ion, applied voltage and treatment time, and may be determined in accordance with the thickness of a polymer layer, an intended purpose of a laminate and the like, and is usually 10-400 nm.

A fact that ions have been implanted can be confirmed by performing element analysis measurement within approximately 10 nm from the surface of the polymer layer, using X-ray photoelectron spectroscopy (XPS).

[Adhesive Resin Layer]

The adhesive resin layer constituting the gas-barrier laminated sheet of the present invention is a layer used for adhesion with an adherend.

Adhesive resin layers include those that are formed using an adhesive resin such as a rubber-based adhesive resin, a polyolefin-based adhesive resin, an epoxy-based adhesive resin or the like.

The use of these adhesive resins makes it possible to form effectively an adhesive resin layer excellent in gas-barrier properties.

A laminated sheet having an adhesive resin layer excellent in gas-barrier properties can intercept penetration of moisture and the like from edge part thereof and, therefore, is used preferably as a material for forming a sealing material.

In the present invention, adhesive resins mean a binder such as a tackifier, an adhesive agent and a tackily adhesive agent.

Rubber-based adhesive resins include adhesive resins containing, as a main component, natural rubber or modified-natural rubber prepared by graft-polymerizing one or two or more monomers selected from (meth)acrylic acid alkyl ester, styrene and (meth)acrylonitrile to natural rubber; adhesive resins containing, as a main component, isoprene rubber, styrene-butadiene rubber, acrylonitrile-butadiene rubber, methyl methacrylate-butadiene rubber, urethane rubber, polyisobutylene-based resin, polybutene resin or the like; and the like.

Among these, an adhesive resin containing a polyisobutylene-based resin as a main component is preferable.

In the present description, a “main component” means a component that amounts to 50% by mass or more in solid contents.

Polyolefin-based adhesive resins include an adhesive resin containing a modified-polyolefin resin as a main component.

A modified-polyolefin-based resin is a polyolefin resin into which a functional group has been introduced, which is obtained by subjecting a polyolefin resin as a precursor to a modification treatment using a modifying agent.

Polyolefin resins include very low-density polyethylene (VLDPE), low-density polyethylene (LDPE), medium-density polyethylene (MDPE), high-density polyethylene (HDPE), linear low-density polyethylene, polypropylene (PP), ethylene-propylene copolymer, olefin-based elastomer (TPO), ethylene-vinyl acetate copolymer (EVA), ethylene-(meth)acrylic acid copolymer, ethylene-(meth)acrylic acid ester copolymer and the like.

The modifying agent for use in a modification treatment of polyolefin resins is a compound having a functional group, that is, a group contributable to a cross-linking reaction to be described later, in a molecule.

Functional groups include a carboxyl group, a carboxylic acid anhydride group, a carboxylic acid ester group, a hydroxyl group, an epoxy group, an amide group, an ammonium group, a nitrile group, an amino group, an imide group, an isocyanate group, an acetyl group, a thiol group, an ether group, a thioether group, a sulfone group, a phosphone group, a nitro group, an urethane group, halogen atoms and the like. Among these, a carboxyl group, a carboxylic acid anhydride group, a carboxylic acid ester group, a hydroxyl group, an ammonium group, an amino group, an imide group and an isocyanate group are preferable, a carboxylic acid anhydride group and an alkoxysylil group are more preferable, and a carboxylic acid anhydride group is particularly preferable.

Epoxy-based adhesive resins include adhesive resins containing a hydrocarbon-modified epoxy resin such as an aliphatic chain-modified epoxy resin, a cyclopentadiene-modified epoxy resin and a naphthalene-modified epoxy resin, an elastomer-modified epoxy resin, or a silicone-modified epoxy resin as a main component.

These adhesive resins may contain a curing agent, a crosslinking agent, a polymerization initiator, a light stabilizer, an anti-oxidant, a tackifier, a plasticizer, an ultraviolet ray absorber, a coloring agent, a resin stabilizer, a filler, pigment, an extending agent, an antistatic agent or the like, if necessary.

These components can be used with suitable selection in accordance with respective adhesive resins.

A process for forming an adhesive resin layer is not particularly limited, and known processes can be used.

For example, an adhesive resin layer can be formed by preparing a solution for forming an adhesive resin layer containing predetermined components, applying this onto the release sheet (B), drying an obtained coating film, and, if necessary, heating the same or irradiating the same with an active energy ray.

As application and drying processes, processes mentioned in the process for forming a gas-barrier layer can be used.

Thickness of the adhesive resin layer can be suitably chosen in consideration of intended use or the like of the gas-barrier laminated sheet. The thickness thereof is, usually, 0.1-1000 μm, preferably 0.5-500 μm, more preferably 1-100 μm, and furthermore preferably 1-10 μm.

When it is 0.1 μm or more, a gas-barrier laminated sheet having sufficient tacky adhesive force or adhesive force is obtained. When it is 1000 μm or less, a gas-barrier laminated sheet has good folding properties, and is advantageous from the viewpoint of productivity and handleability.

A water vapor transmission rate of an adhesive resin layer is preferably 100 g/m²/day or less, and more preferably 50 g/m²/day or less, in terms of thickness of 50 μm.

As a consequence of a fact that a water vapor transmission rate (in terms of thickness of 50 μm) of the adhesive resin layer is 100 g/m²/day or less, penetration of water vapor and the like from an edge part of the laminated sheet can be suppressed more.

The water vapor transmission rate of an adhesive resin layer can be measured, for example, using a sample prepared by forming a tackifier layer on a support having low gas-barrier properties such as a polyethylene terephthalate film. Moreover, a water vapor transmission rate in a case where thickness is 50 μm can be calculated using a fact that the water vapor transmission rate is inversely proportional to thickness of an adhesive resin layer.

[Release Sheet (A)]

The release sheet (A) constituting the gas-barrier laminated sheet of the present invention is one outermost layer of the gas-barrier laminated sheet and is adjacent to the gas-barrier layer.

The release sheet (A) functions as a support when the gas-barrier layer is to be formed, and functions also as a protective layer when the gas-barrier laminated sheet is conveyed or stored.

Eventually, the release sheet (A) and the release sheet (B) to be described later are released and removed, and remaining gas-barrier layer and adhesive resin layer are utilized as a sealing material or the like.

The release sheet (A) includes one prepared by applying a release agent to a releasable base such as paper or plastic film to thereby provide a release agent layer. Releasable bases include paper bases such as glassine paper, coated paper and woodfree paper; laminated paper obtained by laminating these paper bases with a thermoplastic resin such as polyethylene or polypropylene; paper bases obtained by subjecting above-described bases to a filling treatment with cellulose, starch, polyvinyl alcohol, acrylic-styrene resin or the like; alternatively plastic films such as films of polyester including polyethylene terephthalate, polybutylene terephthalate and polyethylene naphthalate and films of polyolefin including polyethylene, polypropylene; and the like.

Release agents include those containing an olefin-based resin such as polyethylene and polypropylene; a rubber-based elastomer such as an isoprene-based resin and a butadiene-based resin; a long-chain alkyl-based resin; an alkyd-based resin; a fluorine-based resin; a silicone-based resin; or the like.

Thickness of the release agent layer is not particularly limited, and is preferably 0.02-2.0 μm, and more preferably 0.05-1.5 μm, in a case where a release agent is applied in a state of solution.

The arithmetic average roughness (Ra) of the surface on the gas-barrier layer side of the release sheet (A) [surface having a release property (release agent layer surface), the same applies hereinafter] is preferably 5 nm or less, and more preferably 3 nm or less. The lower limit value is not particularly determined, and usually is 0.1 nm or more. Accordingly, the arithmetic average roughness (Ra) of the surface on the gas-barrier layer side of the release sheet (A) is preferably 0.1-5 nm, and more preferably 0.1-3 nm.

The maximum cross-section height (Rt) of the surface on the gas-barrier layer side of the release sheet (A) is preferably 100 nm or less, and more preferably 50 nm or less. The lower limit value is not particularly determined, and usually is 10 nm or more. Accordingly, the maximum cross-section height (Rt) of the surface on the gas-barrier layer side of the release sheet (A) is preferably 10-100 nm, and more preferably 10-50 nm.

If the arithmetic average roughness (Ra) or the maximum cross-section height (Rt) becomes too large, irregularity thereof is reflected in the surface of the adjacent gas-barrier layer to thereby generate irregularity also on the surface of the gas-barrier layer, which makes it difficult to obtain a gas-barrier laminated sheet excellent in gas-barrier properties. In particular, in a case of a thin gas-barrier layer, the generation of irregularity on the surface thereof results in a partially very thin site to largely deteriorate gas-barrier properties of the entire gas-barrier layer.

Before a production of the gas-barrier laminated sheet, the arithmetic average roughness (Ra) and the maximum cross-section height (Rt) of the release sheet (A) can be obtained by observing the surface of the release sheet for the production with an optical interferometry microscope.

Moreover, after the production of the gas-barrier laminated sheet, the arithmetic average roughness (Ra) and the maximum cross-section height (Rt) of the surface on the gas-barrier layer side of the release sheet (A) can be obtained by observing, after releasing the release sheet (A) from the gas-barrier laminated sheet, the surface of the gas-barrier layer side of the released release sheet (A) with an optical interferometry microscope.

The observation with an optical interferometry microscope can be performed according to a method described in Example.

[Release Sheet (B)]

The release sheet (B) constituting the gas-barrier laminated sheet of the present invention is the other outermost layer of the gas-barrier laminated sheet, and is adjacent to the adhesive resin layer.

The release sheet (B) functions as a support when the adhesive resin layer is to be formed, and functions also as a protective layer when the gas-barrier laminated sheet is conveyed or stored.

Eventually, the release sheet (B) is released and removed in the same way as the release sheet (A), and the remaining gas-barrier layer and adhesive resin layer are utilized as a sealing material or the like.

The release sheet (B) includes one same as the release sheet (A).

Among these, as the release sheet (B), one having a water vapor transmission rate of 10 g/m²/day or less is preferable, and of 1 g/m²/day or less is more preferable under an atmosphere of 40° C. in temperature and 90% in relative humidity.

As a consequence of a low water vapor transmission rate of the release sheet (B), penetration of water vapor into the adhesive resin layer through the release sheet (B) can be prevented in storage of the gas-barrier laminated sheet of the present invention. Therefore, the gas-barrier laminated sheet can be used preferably as a laminated sheet for forming a sealing material even after a long period of storage.

The release sheet (B) having the above-described water vapor transmission rate can be obtained by using a releasable base constituted of a gas-barrier resin, or by arranging a gas-barrier layer.

Gas-barrier resins include those exemplified above in the explanation of the gas-barrier layer of the gas-barrier laminated sheet.

A gas-barrier layer to be provided for the release sheet (B) includes the gas-barrier layer exemplified above as the gas-barrier layer of the gas-barrier laminated sheet.

The arithmetic average roughness (Ra) of the surface on the adhesive resin layer side of the release sheet (B) [surface having release property (surface on which release agent layer is formed, the same applies hereinafter)] is preferably 5 nm or less, and more preferably 3 nm or less. The lower limit value is not particularly determined, and is usually 0.1 nm or more. Accordingly, the arithmetic average roughness (Ra) of the surface on the adhesive resin layer side of the release sheet (B) is preferably 0.1-5 nm, and more preferably 0.1-3 nm.

The maximum cross-section height (Rt) of the surface on the adhesive resin layer side of the release sheet (B) is preferably 100 nm or less, and more preferably 50 nm or less. The lower limit value is not particularly determined, and is usually 10 nm or more. Accordingly, the maximum cross-section height (Rt) of the surface on the adhesive resin layer side of the release sheet (B) is preferably 10-100 nm, and more preferably 10-50 nm.

In a case where an adhesive resin layer is thin, irregularity of the release sheet (B) is reflected in the surface on the adhesive resin layer side of a gas-barrier layer to thereby generate irregularity also on the surface of the adhesive resin layer side of the gas-barrier layer. Therefore, from a reason similar to that described above, the surface on the adhesive resin layer side of the release sheet (B) is preferably excellent in smoothness.

[Gas-Barrier Laminated Sheet]

The gas-barrier laminated sheet of the present invention has the above-described gas-barrier layer, adhesive resin layer, release sheet (A) and release sheet (B), and has the layer structure of release sheet (A)/gas-barrier layer/adhesive resin layer/release sheet (B).

The gas-barrier laminated sheet of the present invention does not have a base layer and, therefore, is excellent in bending properties. Moreover, it has the gas-barrier layer and adhesive resin layer and, therefore, is excellent in sealing performance.

Substantial thickness (total thickness of layers excluding the release sheet) of the gas-barrier laminated sheet of the present invention is, usually, 0.1-1000 μm, preferably 0.5-500 μm, and more preferably 1-100 μm.

The gas-barrier laminated sheet of the present invention is used suitably as a laminated sheet for an electronic member or for an optical member. In particular, as a consequence of the use of the gas-barrier laminated sheet of the present invention, a sealing material of an organic EL element and the like can effectively be formed.

A method of using the gas-barrier laminated sheet of the present invention is not particularly limited. For example, it is possible to seal an organic EL element by releasing the release sheet (B) from the gas-barrier laminated sheet of the present invention to expose the adhesive resin layer, pressure-bonding the adhesive resin layer to an organic EL element or the like, and then releasing and removing the release sheet (A).

In the same way, by pressure-bonding an exposed adhesive resin layer to other electronic member or optical member, and then releasing and removing the release sheet (A), moisture resistance of the electronic member or optical member can be improved.

2) Process for Producing Gas-Barrier Laminated Sheet

A method for producing the gas-barrier laminated sheet of the present invention is not particularly limited. The gas-barrier laminated sheet of the present invention can be produced, for example, using a process having steps 1-3 below.

Step 1: a step of forming a gas-barrier layer on a surface having a release property of a first release sheet, the surface being 5 nm or less in arithmetic average roughness (Ra) of the surface having a release property and 100 nm or less in maximum cross-section height (Rt) of the surface having a release property to give a release sheet with the gas-barrier layer

Step 2: a step of forming an adhesive resin layer on a surface having a release property of a second release sheet to give a release sheet with the adhesive resin layer; and

Step 3: a step of bonding the release sheet with the gas-barrier layer together with the release sheet with the adhesive resin layer so that the gas-barrier layer of the release sheet with the gas-barrier layer faces the adhesive resin layer of the release sheet with the adhesive resin layer

The first release sheet used in Step 1 becomes eventually the release sheet (A) in the gas-barrier laminated sheet of the present invention.

In Step 1, the gas-barrier layer can be formed by the process explained previously.

The second release sheet used in Step 2 becomes eventually the release sheet (B) in the gas-barrier laminated sheet of the present invention.

In Step 2, the adhesive resin layer can be formed by the process explained previously.

In Step 3, bonding of the release sheet with the gas-barrier layer together with the release sheet with the adhesive resin layer can be performed using a known lamination technology.

3) Electronic Member or Optical Member Including Gas-Barrier Laminated Sheet

The electronic member and the optical member of the present invention are characterized by including the gas-barrier layer and adhesive resin layer derived from the above-described gas-barrier laminated sheet.

The electronic member and optical member of the present invention can be obtained, for example, by releasing the release sheet (B) of the gas-barrier laminated sheet to expose the adhesive resin layer and, after that, sticking the same to a prescribed surface and releasing the remaining release sheet (A).

Examples of the electronic members include flexible substrates of a liquid crystal display member, an organic EL display member, an inorganic EL display member, an electronic paper member, a solar cell, a thermoelectric conversion member and the like; and the like.

Examples of the optical members include optical members of an optical filter, a wavelength conversion device, a dimming device, a polarizing plate and a retardation plate, and the like.

### EXAMPLES

Hereinafter, the present invention will be explained in more detail, referring to Examples. However, the present invention is not limited to following Examples at all.

“Part” and “%” in respective examples are based on mass, unless otherwise noted.

[Surface Roughness of Release Sheet]

Surface roughness of a release sheet was measured by observing a square region of 100 μm on a side at 50× magnification using an optical interferometry microscope (NT8000, manufactured by Veeco Instruments Inc.).

[Surface Roughness of Gas-Barrier Layer]

Surface roughness of a gas-barrier layer was measured by observing a square region of 100 μm on a side of the gas-barrier layer, which was exposed by releasing a releasing sheet from a laminated sheet, at 50× magnification using an optical interferometry microscope (NT8000, manufactured by Veeco Instruments Inc.).

[Measurement of Water Vapor Transmission Rate]

A water vapor transmission rate of each of a gas-barrier laminated sheet and a release sheet (B) was measured using a water vapor transmission rate measurement apparatus (AQUATRAN or PERMATRAN, manufactured by MOCON Inc.) under conditions of 40° C. in temperature and 90% in relative humidity.

A water vapor transmission rate of an adhesive resin layer was measured using a water vapor transmission rate measurement apparatus (L80-5000, manufactured by LYSSY Inc.) under conditions of 40° C. in temperature and 90% in relative humidity. In Table 1, values in terms of 50 μm in thickness are shown.

[Wet Heat Test of Organic EL]

<Manufacturing of Bottom Emission Type Organic EL Element>

By a process below, an anode, a light-emitting layer and a cathode were laminated in this order on a glass substrate to form an organic EL element.

First, an indium tin oxide (ITO) film (thickness: 150 nm, sheet resistance: 30 Ω/square) was formed on a surface of the glass substrate by a sputtering process, and subsequently solvent cleaning and a UV/ozone treatment were performed to manufacture an anode.

On the obtained anode (ITO film), a vapor-deposited film (thickness: 60 nm) of N,N′-bis(naphthalene-1-yl)-N,N′-bis(phenyl)-benzidine (manufactured by Luminescence Technology Corp.), a vapor-deposited film (thickness: 40 nm) of tris (8-hydroxy-quinolinate)aluminum (manufactured by Luminescence Technology Corp.), a vapor-deposited film (thickness: 10 nm) of 2,9-dimethyl-4,7-diphenyl-1,10-phenanthroline (manufactured by Luminescence Technology Corp.), and a vapor-deposited film (thickness: 10 nm) of (8-hydroxy-quinolinolate)lithium (manufactured by Luminescence Technology Corp.) were sequentially formed (formation speed: 0.1-0.2 nm/s) to form a light-emitting layer.

On the obtained light-emitting layer, aluminum (Al) (manufactured by Kojundo Chemical Lab. Co., Ltd.) was vapor-deposited in 100 nm at a speed of 0.1 nm/s to form a cathode, and an organic EL element was obtained.

Meanwhile, a vacuum degree in vapor-deposition was 1×10⁻⁴ Pa or less in all instances.

<Sealing/Wet Heat Test of Element>

In a glove box, a release sheet (B) of a gas-barrier laminated sheet was released, an exposed adhesive resin layer was bonded together with the organic EL element, and then a release sheet (A) was released.

The resultant substance was left at rest under an atmosphere of 23° C. in temperature and 50% in relative humidity for 500 hours, and then an emission state was observed.

In evaluation, one whose emission area ratio calculated by a formula below was 95% or more was determined as good, and one whose emission area ratio was 95% or less was determined as no good.

Meanwhile, in an adhesive resin layer (1), a heat curing reaction was necessary and therefore a wet heat test was performed after the release sheet (A) had been released and then a curing reaction under conditions of 100° C. for 2 hours had been performed.

Emission area ratio (%)=(α₁/α₀)×100

In the formula, α₁ is an emission area of the organic EL element after being set under wet heat conditions, and α₀ is an emission area of the organic EL element before being set under the wet heat conditions.

Release sheets used in Examples or Comparative Examples were as follows.

[Release Sheet (A1)]

A mixture of 55 parts of an addition reaction type silicone resin (SD7328, manufactured by Dow Corning Toray Co., Ltd., solid content: 30%) and 21 parts of a release regulator (aggressive release additive) (SD7292, manufactured by Dow Corning Toray Co., Ltd., solid content: 65%) was dissolved in toluene. To the obtained solution, 2 parts of a platinum catalyst (SRX-212, manufactured by Dow Corning Toray Co., Ltd., solid content: 100%) and 1.9 parts of a Si—H crosslinking agent (SP7297, manufactured by Dow Corning Toray Co., Ltd., solid content: 100%) were added to prepare a release agent coating liquid having solid content concentration of 1.5%.

The obtained release agent coating liquid was applied uniformly by a gravure coating process to an untreated surface of a polyethylene terephthalate film (COSMOSHINE A4100, manufactured by Toyobo Co., Ltd., thickness: 50 μm) as a base so as to give dry thickness of 200 nm. Subsequently, the resultant substance was heated and dried at 135° C. for 1 minute to form a release agent layer, and a release sheet (A1) was obtained.

[Release Sheet (A2)]

The production process of the release sheet (A1) was repeated except that a polyethylene terephthalate film (COSMOSHINE A4300, manufactured by Toyobo Co., Ltd., thickness: 50 μm) was used as a base to give a release sheet (A2).

[Release Sheet (A3)]

The production process of the release sheet (A1) was repeated except that a polyethylene terephthalate film (LUMIRROR U34, manufactured by Toray Industries, Inc., thickness 50: μm) was used as a base to give a release sheet (A3).

[Release Sheet (A4)]

The production process of the release sheet (A1) was repeated except that a polyethylene terephthalate film (DIAFOIL T600, manufactured by Mitsubishi Plastics, Inc., thickness: 50 μm) was used as a base to give a release sheet (A4).

[Release Sheet (A5)]

A commercially available release sheet (SP-PFS50AL-5, manufactured by Lintec Corporation, sheet in which release layer is provided on one surface of polyethylene terephthalate film of thickness 50 μm) was used as a release sheet (A5).

[Release Sheet (B1)]

A commercially available release sheet (SP-PET381031, manufactured by Lintec Corporation, sheet in which silicone release layer is provided on one surface of polyethylene terephthalate film of thickness 38 μm) was used as a release sheet (B1).

[Release Sheet (B2)]

100 parts of heat-curable addition reaction type silicone (KS-847H, manufactured by Shin-Etsu Chemical Co., Ltd.) and 1 part of a curing agent (CAT-PL-50T, manufactured by Shin-Etsu Chemical Co., Ltd.) were diluted with toluene to prepare a release agent coating liquid having a solid content of 2.0%.

On the other hand, for a polyethylene terephthalate film (DIAFOIL T100, manufactured by Mitsubishi Plastics, Inc., thickness: 50 μm), a gas-barrier layer constituted of silicon oxynitride of 60 nm in thickness was formed by a sputtering process. Onto the gas-barrier layer, the above-described release agent coating liquid was applied uniformly by a gravure coating process so as to give dry thickness of 100 nm. Subsequently, the resultant substance was heated and dried at 130° C. for 1 minute using a dryer to form a release agent layer, and a release sheet (B2) was obtained.

### [Production Example 1] Preparation of Adhesive Resin Coating Liquid (1)

100 parts of a modified polyolefin-based resin (UNISTOLE H-200, manufactured by Mitsui Chemicals, Inc., α-olefin polymer, number average molecular weight: 260000), 25 parts of an epoxy resin (EPOLIGHT4000, manufactured by KYOEISHA CHEMICAL Co., LTD., hydrogenated bisphenol A diglycidyl ether), and 1 part of an imidazole-based curing catalyst (CURESOL2E4MZ, manufactured by Shikoku Chemicals Corporation) were dissolved in methyl ethyl ketone to give an adhesive resin coating liquid (1) having solid content concentration of 18%.

### [Production Example 2] Preparation of Adhesive Resin Coating Liquid (2)

100 parts of a copolymer of isobutylene and isoprene (Exxon Butyl 268, manufactured by Japan Butyl Co., Ltd., number average molecular weight: 260,000, content ratio of isoprene: 1.7% by mole) and 20 parts of a tackifier (Quintone A100, manufactured by ZEON CORPORATION) were dissolved in toluene to give an adhesive resin coating liquid (2) having solid content concentration of 20%.

### [Production Example 3] Preparation of Adhesive Resin Coating Liquid (3)

To 100 parts of an ethyl acetate solution (solid content concentration: 18%) of an acrylic acid ester-based copolymer (mass average molecular weight: about 1,200,000) obtained by polymerizing n-butyl acrylate and acrylic acid at a mass ratio of 95:5, 0.1 part of trimethylolpropane tolylene diisocyanate was mixed as a crosslinking agent to give an adhesive resin coating liquid (3).

### Production Example 4

For the release layer surface of the release sheet (A1), a gas-barrier layer (1) constituted of silicon oxynitride having thickness of 200 nm was formed by a sputtering process to give a release sheet (A1) with the gas-barrier layer (1).

### Production Example 5

To the release layer surface of the release sheet (A1), a polysilazane compound (coating agent containing perhydropolysilazane as main component (AQUAMICA NL-110-20, manufactured by Merck Performance Materials Ltd.) was applied by a spin coating process, which was heated at 120° C. for 1 minute to form a layer having thickness of 100 nm containing perhydropolysilazane (polysilazane layer).

Next, using a plasma ion implantation apparatus (RF power source: “RF”56000, manufactured by JEOL Ltd.; high-voltage pulse power source: PV-3-HSHV-0835, manufactured by Kurita Manufacturing Co., Ltd.), under conditions of a gas flow rate of 100 sccm, Duty ratio of 0.5%, applied DC voltage of −10 kV, frequency of 1000 Hz, applied RF electric power of 1000 W, interior pressure of 0.2 Pa, DC pulse width of 5 μsec and treatment time of 200 seconds, ions derived from argon gas were implanted into a surface of the polysilazane layer to form a gas-barrier layer (2), and a release sheet (A1) with the gas-barrier layer (2) was obtained.

### Production Example 6

The procedure in the production example 4 was repeated except that the release sheet (A2) was used in place of the release sheet (A1) to give a release sheet (A2) with the gas-barrier layer (1).

### Production Example 7

The procedure in the production example 4 was repeated except that the release sheet (A3) was used in place of the release sheet (A1) to give a release sheet (A3) with the gas-barrier layer (1).

### Production Example 8

The procedure in the production example 4 was repeated except that the release sheet (A4) was used in place of the release sheet (A1) to give a release sheet (A4) with the gas-barrier layer (1).

### Production Example 9

The procedure in the production example 4 was repeated except that the release sheet (A5) was used in place of the release sheet (A1) to give a release sheet (A5) with the gas-barrier layer (1).

### Production Example 10

To the release layer surface of the release sheet (B1), the adhesive resin coating liquid (1) was applied by a gravure coating process, which was dried at 110° C. for 1 minute to form an adhesive resin layer (1) having thickness of about 1 μm, and a release sheet (B1) with the adhesive resin layer (1) was obtained.

### Production Example 11

The procedure in the production example 10 was repeated except that the adhesive resin coating liquid (2) was used in place of the adhesive resin coating liquid (1) to give a release sheet (B1) with the adhesive resin layer (2).

### Production Example 12

To the release layer surface of the release sheet (B2), the adhesive resin coating liquid (1) was applied by a gravure coating process, which was dried at 110° C. for 1 minute to form a tackifier layer (1) having thickness of about 1 μm, and a release sheet (B2) with the adhesive resin layer (1) was obtained.

### Production Example 13

The procedure in the production example 10 was repeated except that the adhesive resin coating liquid (3) was used in place of the adhesive resin coating liquid (1) to give a release sheet (B1) with the adhesive resin layer (3).

### Example 1

The gas-barrier layer (1) of the release sheet (A1) with the gas-barrier layer (1) obtained in the production example 4 was bonded together with the adhesive resin layer (1) of the release sheet (B1) with the adhesive resin layer (1) obtained in the production example 10, to thereby give a gas-barrier laminated sheet of a configuration of [release sheet (A1)/gas-barrier layer (1)/adhesive resin layer (1)/release sheet (B1)].

### Example 2

The gas-barrier layer (2) of the release sheet (A1) with the gas-barrier layer (2) obtained in the production example 5 was bonded together with the adhesive resin layer (1) of the release sheet (B1) with the adhesive resin layer (1) obtained in the production example 10, to thereby give a gas-barrier laminated sheet of a configuration of [release sheet (A1)/gas-barrier layer (2)/adhesive resin layer (1)/release sheet (B1)].

### Example 3

The gas-barrier layer (1) of the release sheet (A1) with the gas-barrier layer (1) obtained in the production example 4 was bonded together with the adhesive resin layer (2) of the release sheet (B1) with the adhesive resin layer (2) obtained in the production example 11, to thereby give a gas-barrier laminated sheet of a configuration of [release sheet (A1)/gas-barrier layer (1)/adhesive resin layer (2)/release sheet (B1)].

### Example 4

The gas-barrier layer (1) of the release sheet (A2) with the gas-barrier layer (1) obtained in the production example 6 was bonded together with the adhesive resin layer (1) of the release sheet (B1) with the adhesive resin layer (1) obtained in the production example 10, to thereby give a gas-barrier laminated sheet of a configuration of [release sheet (A2)/gas-barrier layer (1)/adhesive resin layer (1)/release sheet (B1)].

### Example 5

The gas-barrier layer (1) of the release sheet (A3) with the gas-barrier layer (1) obtained in the production example 7 was bonded together with the adhesive resin layer (1) of the release sheet (B1) with the adhesive resin layer (1) obtained in the production example 10, to thereby give a gas-barrier laminated sheet of a configuration of [release sheet (A3)/gas-barrier layer (1)/adhesive resin layer (1)/release sheet (B1)].

### Example 6

The gas-barrier layer (1) of the release sheet (A1) with the gas-barrier layer (1) obtained in the production example 4 was bonded together with the adhesive resin layer (1) of the release sheet (B2) with the adhesive resin layer (1) obtained in the production example 12, to thereby give a gas-barrier laminated sheet of a configuration of [release sheet (A1)/gas-barrier layer (1)/adhesive resin layer (1)/release sheet (B2)].

### Comparative Example 1

The gas-barrier layer (1) of the release sheet (A4) with the gas-barrier layer (1) obtained in the production example 8 was bonded together with the adhesive resin layer (1) of the release sheet (B1) with the adhesive resin layer (1) obtained in the production example 10, to thereby give a gas-barrier laminated sheet of a configuration of [release sheet (A4)/gas-barrier layer (1)/adhesive resin layer (1)/release sheet (B1)].

### Comparative Example 2

The gas-barrier layer (1) of the release sheet (A1) with the gas-barrier layer (1) obtained in the production example 4 was bonded together with the adhesive resin layer (3) of the release sheet (B1) with the adhesive resin layer (3) obtained in the production example 13, to thereby give a gas-barrier laminated sheet of a configuration of [release sheet (A1)/gas-barrier layer (1)/adhesive resin layer (3)/release sheet (B1)].

### Comparative Example 3

The gas-barrier layer (1) of the release sheet (A5) with the gas-barrier layer (1) obtained in the production example 9 was bonded together with the adhesive resin layer (1) of the release sheet (B1) with the adhesive resin layer (1) obtained in the production example 10, to thereby give a gas-barrier laminated sheet of a configuration of [release sheet (A5)/gas-barrier layer (1)/adhesive resin layer (1)/release sheet (B1)].

Layer structures and physical properties of respective layers of gas-barrier laminated sheets obtained in Examples and Comparative Examples are shown in Table 1, and test results are shown in Table 2.

TABLE 1

| | Release sheet | | | Gas-barrier | | | Adhesive resin | | Release sheet | |
|---|---|---|---|---|---|---|---|---|---|---|
| | (A) | | | layer | | | layer | | (B) | |
| | | Arithmetic | Maximum | | Arithmetic | Maximum | | Water vapor | | Water vapor |
| | | average | cross-section | | average | cross-section | | transmission | | transmission |
| | | roughness | height | | roughness | height | | rate | | rate |
| | Type | (Ra) [nm] | (Rt) [nm] | Type | (Ra) [nm] | (Rt) [nm] | Type | [g/m²/day] | Type | [g/m²/day] |
| Example 1 | (A1) | 1.8 | 21.2 | (1) | 1.8 | 19.3 | (1) | 49.3 | (B1) | 9.5 |
| Example 2 | (A1) | 1.8 | 21.2 | (2) | 1.8 | 19.3 | (1) | 49.3 | (B1) | 9.5 |
| Example 3 | (A1) | 1.8 | 21.2 | (1) | 1.8 | 19.3 | (2) | 14.2 | (B1) | 9.6 |
| Example 4 | (A2) | 3.1 | 53.6 | (1) | 3.0 | 46.3 | (1) | 49.3 | (B1) | 9.5 |
| Example 5 | (A3) | 4.1 | 95.6 | (1) | 4.1 | 86.4 | (1) | 49.3 | (B1) | 9.4 |
| Example 6 | (A1) | 1.8 | 21.2 | (1) | 1.8 | 19.3 | (1) | 49.3 | (B2) | 0.5 |
| Comparative | (A4) | 13.1 | 158.9 | (1) | 12.5 | 136.8 | (1) | 49.3 | (B1) | 9.5 |
| Example 1 | | | | | | | | | | |
| Comparative | (A1) | 1.8 | 21.2 | (1) | 1.8 | 19.3 | (3) | 815.3 | (B1) | 9.5 |
| Example 2 | | | | | | | | | | |
| Comparative | (A5) | 5.6 | 98.6 | (1) | 5.3 | 89.6 | (1) | 49.3 | (B1) | 9.5 |
| Example 3 | | | | | | | | | | |

TABLE 2

Laminated sheet

| | Water vapor | Organic EL wet |
|---|---|---|
| | transmission rate | heat test |
| | [g/m²/day] | (emission area ratio [%]) |
| Example 1 | 3.6 × 10⁻³ | 99.3 |
| Example 2 | 2.6 × 10⁻³ | 99.5 |
| Example 3 | 3.6 × 10⁻³ | 95.6 |
| Example 4 | 7.0 × 10⁻³ | 96.3 |
| Example 5 | 1.0 × 10⁻² | 91.3 |
| Example 6 | 3.6 × 10⁻³ | 100 |
| Comparative | 3.6 × 10⁻² | 75.3 |
| Example 1 | | |
| Comparative | 5.6 × 10⁻⁴ | 42.5 |
| Example 2 | | |
| Comparative | 2.5 × 10⁻² | 76.5 |
| Example 3 | | |

From Tables 1 and 2, the following are found.

Gas-barrier laminated sheets obtained in Examples of the present application have a low water vapor transmission rate, and are excellent in sealing performance.

On the other hand, each gas-barrier laminated sheet in Comparative Examples 1 and 3 has a rough surface of gas-barrier layer. As the result, a water vapor transmission rate is high and sealing performance is poor.

The gas-barrier layer of the gas-barrier laminated sheet in Comparative Example 2 is excellent in gas-barrier properties and, therefore, a water vapor transmission rate of the gas-barrier laminated sheet is low. However, in an instance where it is used actually as a sealing material, it does not have sufficient sealing performance as a result of influence of the water vapor transmission rate of the adhesive resin layer.

1. A gas-barrier laminated sheet having a layer structure of release sheet (A)/gas-barrier layer/adhesive resin layer/release sheet (B),
wherein arithmetic average roughness (Ra) of a surface on the release sheet (A) side of the gas-barrier layer is 5 nm or less, and maximum cross-section height (Rt) of the surface is 100 nm or less.

2. The gas-barrier laminated sheet according to claim 1, wherein the gas-barrier layer is one that is constituted of an inorganic vapor-deposited film, or one in which a surface of a layer containing a polymer compound has been modified.

3. The gas-barrier laminated sheet according to claim 1, wherein the adhesive resin layer is one that is formed using a rubber-based adhesive resin, a polyolefin-based adhesive resin or an epoxy-based adhesive resin.

4. The gas-barrier laminated sheet according to claim 1, wherein a water vapor transmission rate of the release sheet (B) under an atmosphere of 40° C. in temperature and 90% in relative humidity is 1 g/m²/day or less.

5. The gas-barrier laminated sheet according to claim 1, which is a laminated sheet for an electronic member or for an optical member.

6. A process for producing the gas-barrier laminated sheet according to claim 1, including following steps 1-3:
step 1: forming a gas-barrier layer on a surface having a release property of a first release sheet, the surface being 5 nm or less in arithmetic average roughness (Ra) and 100 nm or less in maximum cross-section height (Rt), to thereby give a release sheet with the gas-barrier layer;
step 2: forming an adhesive resin layer on a surface having a release property of a second release sheet to thereby give a release sheet with the adhesive resin layer; and
step 3: bonding the release sheet with the gas-barrier layer together with the release sheet with the adhesive resin layer so that the gas-barrier layer of the release sheet with the gas-barrier layer faces the adhesive resin layer of the release sheet with the adhesive resin layer.

7. An electronic member or an optical member, including a gas-barrier layer and an adhesive resin layer derived from the gas-barrier laminated sheet according to claim 1.
